(19) United States
(12) Patent Application Publication
(10) Pub. No.: US 2024/0260429 A1
(43) Pub. Date: Aug. 1, 2024

(54) LIGHT EMITTING DISPLAY DEVICE

(71) Applicant: LG Display Co., Ltd, Seoul (KR)

(72) Inventors: Youngjune GO, Gyeonggi-do (KR); Joohwan HWANG, Gyeonggi-do (KR); Wooseok NOH, Gyeonggi-do (KR); Hyejin KIM, Gyeonggi-do (KR)

(73) Assignee: LG Display Co., Ltd, Seoul (KR)

(21) Appl. No.: 18/534,971

(22) Filed: Dec. 11, 2023

(30) Foreign Application Priority Data
Jan. 27, 2023 (KR) 10-2023-0010509

(51) Int. Cl. H10K 59/80; H10K 59/122

(52) U.S. Cl. CPC H10K 59/8792; H10K 59/122

(57) ABSTRACT

A light emitting display device optionally selects any one mode of a narrow viewing angle mode and a wide viewing angle mode and includes a substrate including a first area and a second area adjacent to the first area; a first pixel in the first area; a light blocking layer surrounding the first pixel in the first area; a second pixel in the second area; and a metal patterning layer covering and surrounding the second pixel in the second area.

### CROSS-REFERENCE TO RELATED APPLICATION

This application claims the priority of Korean Patent Application No. 10-2023-0010509 filed on Jan. 27, 2023 which is hereby incorporated by reference in its entirety.

### BACKGROUND

### Field of the Disclosure

The present disclosure relates to a light emitting display device, and more particularly, or example, without limitation, to a light emitting display device, optionally selected any one mode of a narrow viewing angle mode and a wide viewing angle mode.

### Description of the Background

Among display device, a top emission type light emitting display device has a high aperture ratio and provides excellent display quality with high luminance versus power consumption. Additionally, the light emitting display device has a wide viewing angle of close to 180-degree which has the advantage of providing excellent image quality evenly in all directions from the display device.

A light emitting display device having a wide viewing angle may be applied to a variety of applications, for example, by selectively switching to a display state having a narrow viewing angle. In particular, there is an increasing demand for light emitting display devices that may select narrow viewing angle mode and the wide viewing angle mode. The structure for implementing the function of selecting narrow viewing angle mode and wide viewing angle mode is quite expensive, making it not vulnerable to popularization. Therefore, there is a need for structural development of a light emitting display device that may select between narrow viewing angle mode and wide viewing angle mode without special additional element or device.

### SUMMARY

Accordingly, the present disclosure is directed to a light emitting display device that substantially obviates one or more of problems due to limitations and disadvantages described above.

More specifically, the present disclosure is to provide a light emitting display device that may select a narrow viewing angle mode and a wide viewing angle mode.

The present disclosure is also to provide a light emitting display device that may select a narrow viewing angle mode and a wide viewing angle mode without additional elements or devices in the display device.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a light emitting display device includes a substrate including a first area and a second area adjacent to the first area; a first pixel in the first area; a light blocking layer surrounding the first pixel in the first area; a second pixel in the second area; and a metal patterning layer covering and surrounding the second pixel in the second area.

In an example aspect, the light blocking layer is disposed from an edge of the first pixel to a point defined between ⅓ and ½ of a separation width between the first pixel and the second pixel.

In an example aspect, the light blocking layer includes a metal material with a light absorption or light reflectance of 90%, at least. The metal patterning layer includes an organic material with a light transmittance of 90%, at least.

In an example aspect, the light emitting display device further comprises: a first pixel electrode in the first pixel; a second pixel electrode in the second pixel; a bank disposed between the first pixel electrode and the second electrode to define a first emission area of the first pixel and a second emission area of the second pixel; an emission layer over the first pixel electrode, the bank and the second pixel; a common electrode on the emission layer; and a first protective layer on the common electrode.

In an example aspect, the metal patterning layer is deposited on the first protective layer, and disposed within the first emission area and the second emission area. the metal patterning layer is further disposed from the second emission area on the bank to a position defined at ½ to ⅔ between the first emission area and the second emission area.

In an example aspect, the light blocking layer is disposed from the first emission area on the first protective layer to a position defined at ⅓ to ½ between the first emission area and the second emission area.

In an example aspect, the metal patterning layer and the light blocking layer is disposed on the first protective layer. The light emitting display device further comprises: a second protective layer on the metal patterning layer and the light blocking layer.

In an example aspect, the first area and the second area have a strip shape extending in a first direction, and are arranged alternately in a second direction different from the first direction.

In an example aspect, the first direction is a vertical direction on the substrate in a plan view. The second direction is a horizontal direction on the substrate in the plan view.

In an example aspect, the first direction is a horizontal direction on the substrate in a plan view. The second direction is a vertical direction on the substrate in the plan view.

In an example aspect, a first viewing angle of the first area is 30-degree, at most. A second viewing angle of the second area is 70-degree, at least.

In an example aspect, in the narrow viewing angle mode, the first pixel emits lights, and the second pixel does not emit lights.

In an example aspect, the light blocking layer includes at least a metal material including ytterbium (Yb), calcium (Ca), titanium (Ti), magnesium (Mg), barium (Ba), silver (Ag), sliver-ytterbium (Ag—Yb) alloy and silver-magnesium (Ag—Mg) alloy.

In an example aspect, the metal patterning layer includes a carbon organic material having a 3-(Biphenyl-4-yl)-5-(4-tert1butylphenyl)-4-phenyl-4H-1, 2, 4-triazole (TAZ).

In an example aspect, the light blocking layer is disposed at an area where the metal patterning layer is not disposed.

The light emitting display device according to the present disclosure has a structure for optionally selecting a narrow viewing angle mode and a wide viewing angle mode. Furthermore, the light emitting display device according to the present disclosure may select a narrow viewing angle mode and a wide viewing angle mode without additional equipment or additional elements or devices. Since the light emitting display device according to the present disclosure provides a high aperture ratio, it may provide high luminance with low power consumption. In particular, by applying the light emitting display device according to the present disclosure to a vehicle structure in which a display device is installed extending integrally from the driver's seat to the passenger seat of the dashboard, the image provides from the passenger seat may not be selectively detected by the driver, so that the driving safety may be secured.

In addition to the effects of the present disclosure mentioned above, other features and advantages of this specification are described below, or may be clearly understood by those skilled in the art from such description or explanation.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this disclosure, illustrate aspects of the disclosure and together with the description serve to explain the principle of the disclosure.

In the drawings:

FIG. 1 is a plane view illustrating a schematic structure of a light emitting display device according to a first aspect of the present disclosure.

FIG. 2 is a circuit diagram illustrating a structure of one pixel disposed in a light emitting display device according to the first aspect of the present disclosure.

FIG. 3 is an enlarged plan view illustrating a structure of one pixel disposed in the light emitting display device according to a first aspect of the present disclosure.

FIG. 4 is a cross-sectional view, along cutting line I-I′ in FIG. 3, illustrating a structure of a light emitting display device according to the first aspect of the present disclosure.

FIG. 5 is an enlarged plan view illustrating an arrangement structure of pixels arrayed in the light emitting display device according to the first aspect of the present disclosure.

FIG. 6 is an enlarged cross-sectional view, along the cutting line II-II′, illustrating structures of a narrow viewing angle area and a wide viewing angle area in the light emitting display device according to the first aspect of the present disclosure.

FIG. 7 is an enlarged plan view illustrating an arrangement structure of the light emitting display device according to a second aspect of the present disclosure.

FIG. 8 is an enlarged plan view illustrating an arrangement structure of the light emitting display device according to a third aspect of the present disclosure.

FIG. 9 is an enlarged cross-sectional view, along cutting line III-III′, illustrating structures of a light emitting display device according to the third aspect of the present disclosure.

FIG. 10 is an enlarged plan view illustrating an arrangement structure of the light emitting display device according to a fourth aspect of the present disclosure.

FIG. 11 is an enlarged plan view illustrating an arrangement structure of the light emitting display device according to a fifth aspect of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to aspects of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example aspects of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted. Any implementation described herein as an “example” is not necessarily to be construed as preferred or advantageous over other implementations.

Reference will now be made in detail to the exemplary aspects of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various aspects of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

The terms, such as “below,” “lower,” “above,” “upper” and the like, may be used herein to describe a relationship between item(s) as illustrated in the drawings. It will be understood that the terms are spatially relative and based on the orientation depicted in the drawings.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked,” “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, an example of a display device according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

Hereinafter, referring to FIGS. 1 to 6, a first aspect of the present disclosure will be described. FIG. 1 is a plane view illustrating a schematic structure of a light emitting display device according to the present disclosure. In FIG. 1, X-axis refers to the direction parallel to the scan line, Y-axis refers to the direction of the data line, and Z-axis refers to the height direction of the display device.

Referring to FIG. 1, the light emitting display device according to a first aspect of the present disclosure comprises a substrate 110, a gate (or scan) driver 200, a pad portion 300, a source driving IC (Integrated Circuit) 410, a flexible circuit film 430, a circuit board 450, and a timing controller 500.

The substrate 110 may include a rigid material or a flexible material. As an example, the substrate 110 may include an electrical insulating material, a semiconductor material or a conductive material, without being limited thereto. As an example, the substrate 110 may include a transparent material or an opaque material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing images (e.g., the video images), may be defined as the majority middle area of the substrate 110, but it is not limited thereto. In the display area AA, a plurality of pixels P are arranged in a matrix manner. Further, the display area AA includes scan lines (or gate lines) 50 and data lines 60 are disposed on the substrate 110. One pixel P may include a plurality of sub-pixels. Here, as an example, pixel P means one sub-pixel. Each pixel P is disposed in an area where the scan lines 50 running along the X-axis and the data lines 60 running along the Y-axis intersect.

The non-display area NDA, which is an area not representing images (e.g., the video images), may be defined at the circumference areas of the substrate 110 surrounding all or some of the display area AA. In the non-display area NDA, the gate driver 200 and the pad portion 300 may be formed or disposed. Embodiments are not limited thereto. The gate driver 200 may also be separately disposed and connected to the non-display area NDA, for example, by a tape automated bonding (TAB) method, a chip-on-glass (COG) method, a chip on film (COF) method, etc.

The gate driver 200 may supply the scan (or gate) signals to the scan lines according to the gate control signal received from the timing controller 500 through the pad portion 300. The gate driver 200 may be formed at the non-display area NDA at any one or more outside edge portion of the display area AA on the substrate 110, as a GIP (gate driver in panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110. As an example, at least one of the transistors for shift registers of the gate driver 200 may be formed in the same process and/or in a same structure as at least one of the transistors for driving the pixels in the display area AA, without being limited thereto. As an example, at least one of the transistors for shift registers of the gate driver 200 may be separately formed from the transistors for driving the pixels in the display area AA.

The pad portion 300 may be disposed in the non-display area NDA at one or more side edges of the display area AA of the substrate 110. The pad portion 300 may include data pads connected to each of the data lines, driving current pads connected to the driving current lines, a high-potential pad receiving a high potential voltage, and/or a low-potential pad receiving a low potential voltage.

The source driving IC 410 may receive the digital video data and the source control signal from the timing controller 500. The source driving IC 410 may convert the digital video data into the analog data voltages according to the source control signal and then supply them to the data lines. When the source driving IC 410 is made as a chip type, it may be installed on the flexible circuit film 430 as a chip on film (COF) type or chip on plastic (COP) type, without being limited thereto. As an example, the source driving IC 410 may be directly formed on the substrate 110 or on the circuit board 450, without being limited thereto.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430. Embodiments are not limited thereto.

The circuit board 450 may be attached to the flexible circuit film 430. The circuit board 450 may include a plurality of circuits implemented as the driving chips. For example, the circuit board 450 includes a timing controller 500. The circuit board 450 may be a printed circuit board or a flexible printed circuit board.

The timing controller 500 may receive the digital video data and the timing signal from an external system board through the line cables of the circuit board 450, or may generate digital video data and/or the timing signal by itself. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and/or mounted on the substrate 110.

In the display area AA, a plurality of pixels P are arranged in a matrix manner. A plurality of pixels P may be divided into columns. For example, odd-numbered columns may be defined as the first area, and even-numbered columns may be defined as the second area. The first area may be defined as a narrow viewing angle area NVA, and the second area may be defined as a wide viewing angle area WVA.

A light blocking layer 79 is disposed around the pixel P located in the narrow viewing angle area NVA, which is the first area. The light blocking layer 79 may function to narrow the diffusion angle of light that provides image information from the emission area EA of the pixel P. For example, light going to the front direction is allowed to travel as is, but light going to the side direction is blocked by the light blocking layer 79. As a result, the light emitted from the emission area EA of the narrow viewing angle area NVA is provided only in the front direction.

On the other hand, the light blocking layer 79 is not disposed around the pixel P located in the wide viewing angle area WVA, which is the second area. Accordingly, light emitted from the emission area EA of the pixels P disposed in the second area is provided in the front and side directions. Embodiments are not limited thereto. As an example, the light blocking layer 79 may be also disposed around the pixel P located in the wide viewing angle area WVA, with a smaller width as compared with the narrow viewing angle area NVA.

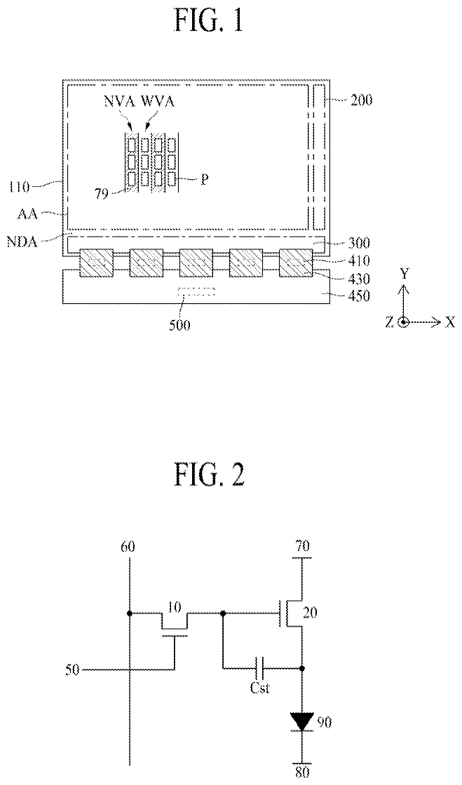

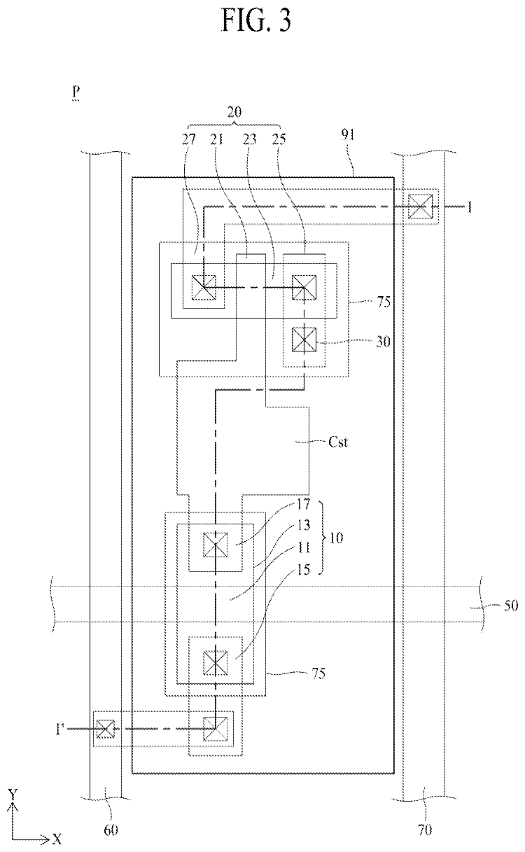

Hereinafter, referring to FIGS. 2 to 4, a first aspect of a light emitting display device according to a first aspect of the present disclosure will be explained. FIG. 2 is a circuit diagram illustrating a structure of one pixel disposed in a light emitting display device according to the first aspect of the present disclosure. FIG. 3 is an enlarged plan view illustrating a structure of one pixel disposed in the light emitting display device according to a first aspect of the present disclosure.

Firstly, referring to FIGS. 1 to 3, a light emitting display device includes a plurality of pixels P arrayed in a matrix manner. Each pixel P of the light emitting display device may be defined by a scan line 50, a data line 60 and a driving current line 70. Each pixel P may include a switching thin film transistor 10, a driving thin film transistor 20, a light emitting diode 90 and a storage capacitance 40. The driving current line 70 may be supplied with a high-level voltage for driving the light emitting diode 90. Embodiments are not limited thereto. As an example, one or more components (e.g., transistors or storage capacitance, etc.) could be further included in each pixel P.

A switching thin film transistor 10 and a driving thin film transistor 20 may be formed on a substrate 110. For example, the switching thin film transistor 10 may be configured to be connected to the scan line 50 and the data line 60. The switching thin film transistor 10T may include a gate electrode 11, a semiconductor layer 13, a source electrode 15 and a drain electrode 17. The gate electrode 11 may be linked to or branched from the scan line 50. The semiconductor layer 13 may be disposed as crossing the gate electrode 11. The overlapped portion of the semiconductor layer 13 with the gate electrode 11 may be defined as the channel area. The source electrode 15 may be connected to or branched from the data line 60, and the drain electrode 17 may be connected to the driving thin film transistor 20. The source electrode 15 may be one side of the semiconductor layer 13 from the channel area, and the drain electrode 17 may be the other side of the semiconductor layer 13. By supplying the data signal to the driving thin film transistor 20, the switching thin film transistor 10 may play a role of selecting a pixel P which would be driven.

The driving thin film transistor 20 may play a role of driving the light emitting diode 90 of the pixel P selected by the switching thin film transistor 10. The driving thin film transistor 20 may include a gate electrode 21, a semiconductor layer 23, a source electrode 25 and a drain electrode 27. The gate electrode 21 of the driving thin film transistor 20 may be connected to the drain electrode 17 of the switching thin film transistor 10. For example, the gate electrode 21 of the driving thin film transistor 20 may be extended from the drain electrode 17 of the switching thin film transistor 10. In the driving thin film transistor 20, the drain electrode 27 may be connected to or branched from the driving current line 70, and the source electrode 25 may be connected to the pixel electrode (or anode electrode) 91 of the light emitting diode (or light emitting element) 90. The semiconductor layer 23 may be disposed as crossing over the gate electrode 21. In the semiconductor layer 23, the overlapped portion with the gate electrode 21 may be defined as a channel area. The source electrode 25 may be connected at one side of the semiconductor layer 23 from the channel area, and the drain electrode 27 is connected to the other side of the semiconductor layer 23. A storage capacitance (or capacitor) 40 may be disposed between the gate electrode 21 of the driving thin film transistor 20 and the pixel electrode 91 of the light emitting diode 90.

The light emitting diode 90 may include a pixel electrode 91, an emission layer 93, and a common electrode (or cathode electrode) 95. The light emitting diode 90 may provide an image by emitting light according to the current controlled by the driving thin film transistor 20. The light emitting diode 90 may generate light according to the current controlled by the driving thin film transistor 20. The driving thin film transistor 20 may control the amount of current flowing from the driving current line 70 to the light emitting diode 90 according to the voltage difference between the gate electrode 21 and the source electrode 25. The pixel electrode 91 of the light emitting diode 90 may be connected to the source electrode 25 of the driving thin film transistor 20. The common electrode 95 (or, cathode electrode) may be connected to a low-power line 80 supplied with the low-potential voltage. Therefore, the light emitting diode 90 may be driven by the electric current flowing from the driving current line 70 to the low power line 80 controlled by the driving thin film transistor 20.

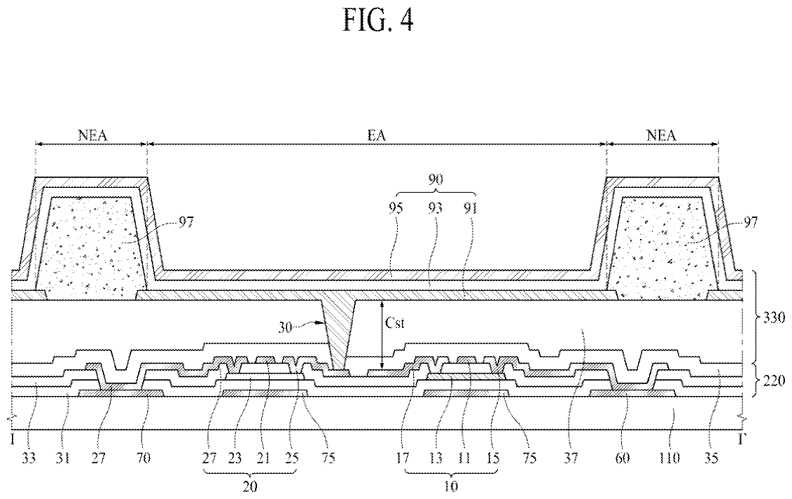

Next, referring to FIG. 4, a cross-sectional structure of the light emitting display device according to the first aspect of the present disclosure will be explained. FIG. 4 is a cross-sectional view, along the cutting line I-I′ in FIG. 3, illustrating a structure of a light emitting display device according to the first aspect of the present disclosure. Referring to FIG. 4, a light emitting display device according to the first exemplary embodiment comprises a substrate 110, a driving layer 220 and a light emitting layer 330. In the cross-sectional structure, a data line 60, a driving current line 70 and a light shielding layer 75 are formed on the substrate 110, without being limited thereto. The data line 60 running along the Y-axis may be disposed at the right side of the pixel P in the cross-sectional structure. As an example, the data line 60, the driving current line 70 and the light shielding layer 75 may be formed on different layers.

The driving current line 70 may be arranged on the left side of the pixel P in parallel with the data line 60 and spaced a certain distance apart in the cross-sectional structure. Here, the light shielding layer 75 may have an island shape, but is not limited thereto. The light shielding layer 75 may be arranged to overlap the semiconductor layers 13 and 23 formed later. In some cases, the light shielding layer 75 may be omitted.

A buffer layer 31 is stacked on the data line 60, the driving current line 70 and the light shielding layer 75. Thin film transistors 10 and 20 are formed on the buffer layer 31. The thin film transistors 10 and 20 have a structure in which gate electrodes 11 and 21, gate insulating layer 33, semiconductor layers 13 and 23 and source-drain electrodes 15-17 and 25-27 are stacked.

A passivation layer 35 is deposited on the substrate 110 as covering the thin film transistors 10 and 20. The passivation layer 35 may be made of an inorganic material such as silicon oxide or silicon nitride. These stacked structures may be referred to as a driving layer 220. The surface of the substrate 110 on which the driving layer 220 including thin film transistors 10 and 20 is formed may be an uneven condition, and a planarization layer 37 may be formed thereon to flatten or compensate the uneven surface condition. To uniformly compensate for the height difference of the surface, the planarization layer 37 may be made of an organic material having a thickness of 2 μm (micrometer) to 3 μm (micrometer), without being limited thereto.

A pixel contact hole 30 is formed at the planarization layer 37. The pixel contact holes 30 are disposed one by one for each pixel P, and each pixel contact hole 30 exposes a portion of the source electrode 25 of the driving thin film transistor 20.

A pixel electrode 91 (or anode electrode) is formed on the planarization layer 37. The pixel electrode 91 is connected to the source electrode 25 of the driving thin film transistor 20 via the pixel contact hole 30. In the case of the bottom emission type, the pixel electrode 91 may be formed of a transparent conductive material. For example, the pixel electrode 91 may include an oxidizing conductive material such as indium-zinc-oxide (IZO) and indium-tin-oxide (ITO), without being limited thereto.

In the case of the top emission type, the pixel electrode 91 may be formed of a metal material with excellent light reflectance. For example, the pixel electrode 91 includes one of silver (Ag), aluminum (Al), molybdenum (Mo), gold (Au), magnesium (Mg), calcium (Ca), and barium (Ba), or an alloy material of two or more from them. Embodiments are not limited thereto. As an example, even in the case of the top emission type, the pixel electrode 91 may be formed of a material with little light reflectance or a transparent conductive material, without being limited thereto. The light emitting display device according to the first aspect of the present disclosure is described based on the top emission type.

A bank 97 is formed on the pixel electrode 91. The bank 97 covers the edge area of the pixel electrode 91, and exposes most of the central area of the pixel electrode 91 to define an emission area EA. The area covered by bank 97 may be defined as a non-emission area NEA.

An emission layer 93 is deposited on the pixel electrode 91 and bank 97. The emission layer 93 may be deposited on entire of the display area AA of the substrate 110 as covering the pixel electrode 91 and the bank 97. Embodiments are not limited thereto. As an example, the emission layer 93 may be individually disposed in each pixel, without being limited thereto. In the case of an organic light emitting display device, the emission layer 93 may include an organic material. In the case of an inorganic light emitting display device, the emission layer 93 may be made of an inorganic material.

For an aspect, the emission layer 93 may include at least two emission parts for generating white light. For example, the emission layer 93 may include a first emission part and a second emission part vertically stacked for generating white light by mixing the first light from the first emission part and the second light from the second emission part. Embodiments are not limited thereto. As an example, the emission layer 93 may include at least two emission parts for generating a light of a color other than white light.

For another example, the emission layer 93 may include any one of a blue emission part, a green emission part, and a red emission part for generating light corresponding to a color set in each pixel. Embodiments are not limited thereto. Emission parts of other colors are also possible. Further, as an example, the light emitting diode 90 may include a functional layer for improving light emitting efficiency and/or lifetime of the emission layer 93 without being limited thereto.

The common electrode 95 (or cathode electrode) is deposited on the entire surface of the substrate 110 to make surface contact with the emission layer 93. The common electrode 95 is formed over the entire substrate 110 to be commonly connected to the emission layer 93 deposited in all pixels P. Embodiments are not limited thereto. As an example, the common electrode 95 may be individually disposed in each pixel, or in some pixels, without being limited thereto. Since the present disclosure is related to the top emission type, the common electrode 95 may include a transparent conductive material. For example, the common electrode 95 may be made of an oxide material including indium-tin-oxide (ITO) or indium-zinc-oxide (IZO), without being limited thereto.

A light emitting diode 90 is formed in the emission area EA where the pixel electrode 91, the emission layer 93 and the common electrode 95 are sequentially stacked. The pixel electrode 91 is disposed within an area of one pixel P. The emission layer 93 and the common electrode 95 are sequentially stacked on the pixel electrode 91. A portion of the pixel electrode 91 that contact the emission layer 93 to generate light may be defined as the emission area EA. The stacked structures including the planarization layer 37, the light emitting diode 90 may be referred to as a light emitting layer 330.

Even though it is not shown in figures, an encapsulation layer may be further disposed on the light emitting diode 90. The encapsulation layer may have a structure in which a first inorganic layer, an organic layer and a second inorganic layer are sequentially stacked, without being limited thereto.

Hereinafter, referring to FIG. 5, the plane structure of pixels arranged in the light emitting display device according to the first aspect of the present disclosure will be described in detail. FIG. 5 is an enlarged plan view illustrating an arrangement structure of pixels arrayed in the light emitting display device according to the first aspect of the present disclosure. The arrange relationship between the bank and the pixel electrode is explained on the plan view.

A plurality of pixels P are arrayed in a matrix manner with rows and columns. The odd numbered columns are defined as the narrow viewing angle area NVA. The even numbered columns are defined as the wide viewing angle area WVA. The narrow viewing angle area NVA and the wide viewing angle area WVA are arranged alternately along the horizontal direction (X-axis). Embodiments are not limited thereto. As an example, the odd numbered columns may be defined as the wide viewing angle area WVA, and the even numbered columns may be defined as the narrow viewing angle area NVA.

At the narrow viewing angle area NVA, a light blocking layer 79 is disposed to partially or fully surround the pixels P. The light blocking layer 79 may be formed of a material with a light absorption rate of 80% or more or 90% or more, without being limited thereto. Alternatively, the light blocking layer 79 may include a material (e.g., metal material) with a light reflectance of 80% or more or 90% or more, without being limited thereto. For an example, the light blocking layer 79 may include any one of metal materials such as ytterbium (Yb), calcium (Ca), titanium (Ti), magnesium (Mg), barium (Ba) and silver (Ag). For another example, the light blocking layer 79 may be made of a metal material including at least one of silver-ytterbium (Ag—Yb) alloy or silver-magnesium (Ag—Mg) alloy.

In addition, the light blocking layer 79 may have a thickness of at least 200 Å or more to maintain a high light reflectance or high light absorption rate, without being limited thereto. In particular, the light blocking layer 79 may have a thickness of 200 Å and 1,000 Å. Even though the light blocking layer 79 is made of a metal material, when the thickness is 200 Å or less, the light transmittance may be 40% or more. In this case, the light blocking layer 79 may not properly implement the function to narrow the optical viewing angle by blocking light. Additionally, when the thickness of the light blocking layer 79 is greater than 1,000 Å, the manufacturing process time may be too long and cost may be too expensive.

Meanwhile, in the wide viewing angle area WVA, a metal patterning layer 71 is arranged to partially or fully surround the pixels P. The metal patterning layer 71 may include a transparent organic material. Specifically, the metal patterning layer 71 may include an organic material having a light transmittance of 90% or higher, without being limited thereto. For example, the metal patterning layer 71 may be made of carbon organic materials including 3-(Biphenyl-4-yl)-5-(4-tert1butylphenyl)-4-phenyl-4H-1,2,4-triazole (TAZ).

The metal patterning layer 71 has low-adhesion property with high interfacial energy between the metal material and the metal patterning layer 71. Therefore, when the metal patterning layer 71 is first formed and the metal material is deposited thereon, the metal material is not adsorbed but desorbed on the surface of the metal patterning layer 71. As a result, nucleation that causes metal materials to be deposited into a metal layer does not occur. Accordingly, the metal material is deposited on the areas in which the interfacial energy is low due to absence of the metal patterning layer 71, and metal adhesion energy is high.

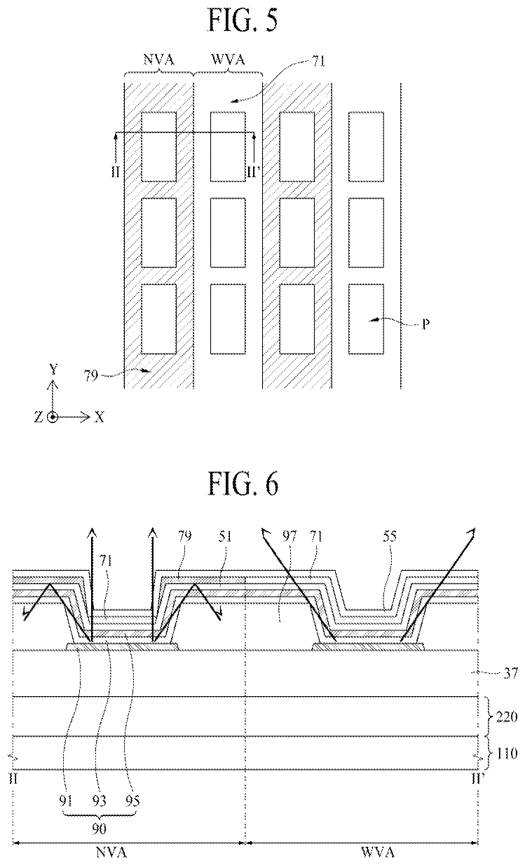

Hereinafter, referring to FIG. 6, the cross-sectional structures of the narrow viewing angle area and the wide viewing angle area in the light emitting display device according to the first aspect of the present disclosure will be described. FIG. 6 is an enlarged cross-sectional view, along the cutting line II-II′, illustrating structures of a narrow viewing angle area and a wide viewing angle area in the light emitting display device according to the first aspect of the present disclosure.

The substrate 110 includes a narrow viewing angle area NVA and a wide viewing angle area WVA. On the substrate 110, a driving layer 220 is disposed over the narrow viewing angle area NVA and the wide viewing angle area WVA. The structure of the driving layer 220 is the same as explained with the FIG. 4, so the same description will not be duplicated or be briefly given.

A planarization layer 37 is deposited on the driving layer 220. A light emitting diode 90 is formed on the planarization layer 37. The light emitting diode 90 has a structure in which a pixel electrode 91, an emission layer 93 and a common electrode 95 are sequentially stacked. The detailed description for the light emitting diode 90 is the same as described with FIG. 4, so the detailed description will not be duplicated or be briefly given.

A first protection layer 51 is deposited on the common electrode 95. The first protection layer 51 may be deposited over the entire surface of the substrate 110.

On the first protective layer 51, a metal patterning layer 71 is formed over the whole of the wide viewing angle area WVA. In addition, the metal patterning layer 71 is also deposited on the emission area EA within the narrow viewing angle area NVA corresponding to the emission area EA.

A light blocking layer 79 is formed on the first protective layer 51 within a portion where the metal patterning layer 71 is not deposited. Specifically, as an example, on the upper surface of the bank 97 placed between the pixel electrode 91 of the narrow viewing angle area NVA and the pixel electrode 91 of the wide viewing angle area WVA, the light blocking layer 79 may be disposed only over the narrow viewing angle area NVA. As an example, the light blocking layer 79 may be disposed only over the narrow viewing angle area NVA corresponding to half (½) of the width of the bank 97, without being limited thereto. Additionally, the light blocking layer 79 may be deposited on the sidewall of the bank 97 in the narrow viewing angle area NVA. The light blocking layer 79 may be disposed on the upper surface of the bank 97 in an area corresponding to at most ½ of the width and at least ⅓ of the width of the bank 97.

A second protective layer 55 may be deposited on the metal patterning layer 71 and the light blocking layer 79. The first protective layer 51 and the second protective layer 55 may be formed of a transparent inorganic material such as silicon oxide (SiOx) and silicon nitride (SiNx), without being limited thereto.

In the case of having the structure shown in FIG. 6, light generated from the light emitting diode 90 disposed in the narrow viewing angle area NVA is provided only from an open area which is formed between two light blocking layers 79 disposed on side walls of both of the adjacent banks 97 facing the emission area EA. On the other hand, light going to the side direction is reflected or absorbed by the light blocking layer 79 and is not provided to the side directions in the narrow viewing angle area NVA. Accordingly, light emitted from the narrow viewing angle area NVA may have a viewing angle range of less than 30 degrees, at most, without being limited thereto. Here, the viewing angle range refers to the angle radiated to both sides based on the vertical direction with respect to the surface of the substrate 110.

In the meantime, light generated from the light emitting diode 90 disposed in the wide viewing angle area WVA is provided in a wide viewing angle range covering the front direction and the side direction. For example, Light emitted from the wide viewing angle area WVA may have a viewing angle range of 70 degrees, at least, without being limited thereto.

In the display device according to the first aspect of the present disclosure, the display device may operate in a narrow viewing angle mode by selectively driving only the pixels P disposed in the narrow viewing angle area NVA. In this case, the image information from the display device is not provided to the observers located in the side direction, but the image information is provided only to the observer located in the front direction from the display device. Alternatively, the display device may operate in a wide viewing angle mode by selectively driving only the pixels P arranged in the wide viewing angle area WVA. In this case, image information is provided to all observers located in the frontal and side directions of the display device.

The light emitting display device according to the first aspect is described as a case in which the light blocking layer 79 is disposed on the left side, right side, the upper side and lower side of the pixel P of the narrow viewing angle area NVA, in a plan view. Therefore, not only the left and right viewing angle but also upper and lower viewing angle may have the narrowing viewing angle, i.e., the horizontal viewing angle and the vertical viewing angle, in a plan view have the narrow viewing angle.

In some cases, when it is desired to have a wide vertical viewing angle, the light blocking layer 79 may be removed from the upper side and the lower side of the pixel, and the light blocking layer 79 may be remained on the left and right sides. On the other hand, when the horizontal viewing angle is to have the wide viewing angle and the vertical viewing angle is to have the narrow viewing angle, the light blocking layer 79 may be removed from the left and right sides of the pixel, and the light blocking layer 79 may be remained on the upper and lower sides. Embodiments are not limited thereto. As an example, the light blocking layer 79 may be removed from at least one of the left side, the right side, the upper side, and the lower side of the pixel, and the light blocking layer 79 may be remained on the remaining sides.

In the first aspect, the light blocking layer 79 may be disposed from an edge of the emission area EA formed in the narrow viewing angle area NVA to a point defined between ⅓ and ½ of a separation width (e.g., a width of the bank) between the narrow viewing angle area NVA and the wide viewing angle area WVA. In other word, in the first aspect, the border between the narrow viewing angle area NVA and the wide viewing angle area WVA is set on a position defined at ⅓ point, ½ point or ⅔ point of a separation width (e.g., a width of the bank) between the pixel electrode 91 (or the emission area EA) of the narrow viewing angle area NVA and the pixel electrode 91 (or the emission area EA) of the wide viewing angle area WVA.

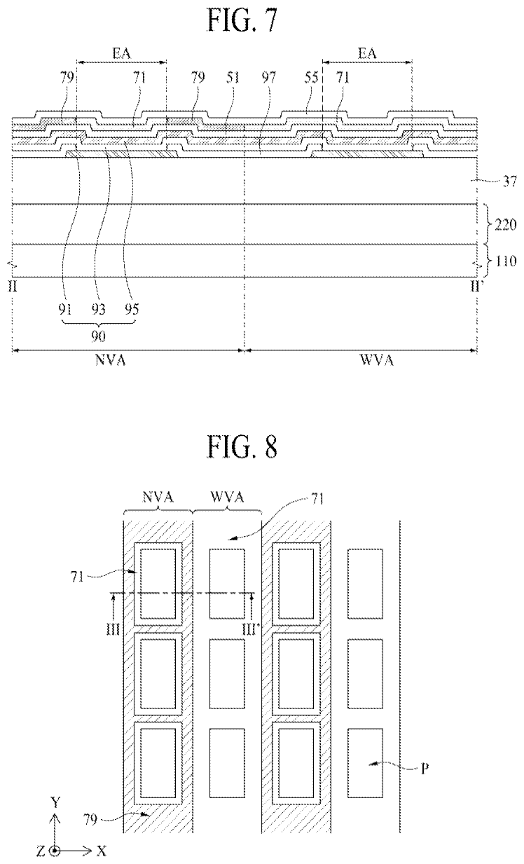

Hereinafter, referring to FIG. 7, the structure of the light emitting display device according to a second aspect of the present disclosure will be described. FIG. 7 is an enlarged plan view illustrating an arrangement structure of the light emitting display device according to a second aspect of the present disclosure.

With reference the FIG. 7, the structure of the light emitting display device according to the second aspect is very similar with that of the first aspect. In the first aspect, as the bank 97 is formed of an organic material, the bank 97 has a trapezoidal shape as an example. On the other hand, in the second aspect, as the bank 97 is formed of an inorganic material, the bank 97 has a thin film shape.

In the light emitting display device according to the second aspect, the substrate 110 includes a narrow viewing angle area NVA and a wide viewing angle area WVA. On the substrate 110, a driving layer 220 is formed over the narrow viewing angle area NVA and the wide viewing angle area WVA.

A planarization layer 37 is deposited on the driving layer 220. A light emitting diode 90 is formed on the planarization layer 37. The light emitting diode 90 has a structure in which a pixel electrode 91, an emission layer 93 and a common electrode 95 are sequentially stacked.

A first protection layer 51 is deposited on the common electrode 95. The first protection layer 51 may be deposited over the entire surface of the substrate 110.

On the first protective layer 51, a metal patterning layer 71 is formed over the whole of the wide viewing angle area WVA. In addition, the metal patterning layer 71 is also deposited on the emission area EA within the narrow viewing angle area NVA corresponding to the emission area EA.

A light blocking layer 79 is formed on the first protective layer 51 within a portion where the metal patterning layer 71 is not deposited. A second protective layer 55 may be deposited on the metal patterning layer 71 and the light blocking layer 79.

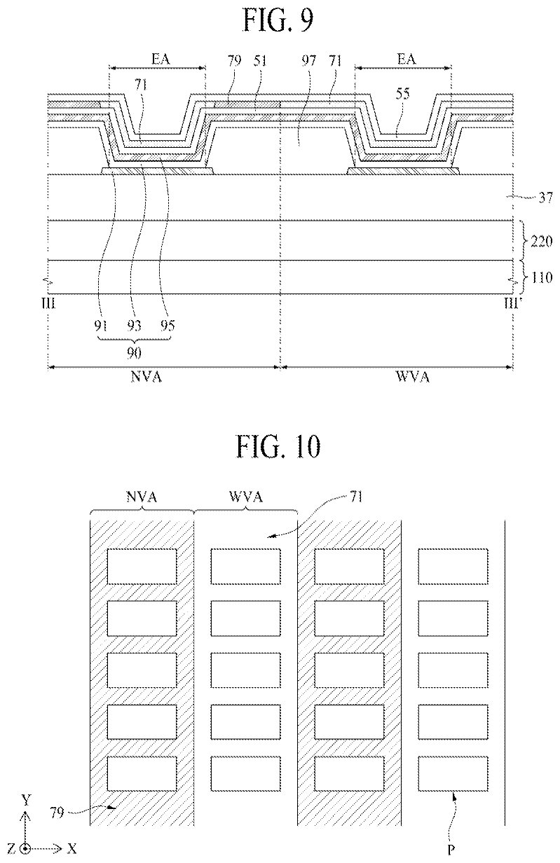

Hereinafter, referring to FIGS. 8 and 9, the structure of the light emitting display device according to a third aspect of the present disclosure will be described. FIG. 8 is an enlarged plan view illustrating an arrangement structure of the light emitting display device according to a third aspect of the present disclosure. FIG. 9 is an enlarged cross-sectional view, along the cutting line III-III′, illustrating structures of a light emitting display device according to the third aspect of the present disclosure.

The structure of the light emitting display device according to the third aspect is very similar with that of the first aspect. The difference is that, in the third aspect, the ranges of the metal patterning layer 71 and the light blocking layer 79 disposed in the narrow viewing angle area NVA are formed to be wider than those of the first aspect.

In detail, referring to FIG. 8, the metal patterning layer 71 surrounding the pixel P is further included between emission area EA and the light blocking layer 79 in the narrow viewing angle area NVA. That is, the metal patterning layer 71 is somewhat extended from the emission area EA to outer direction. Referring to FIG. 9, in the narrow viewing angle area NVA, the light blocking layer 79 is only partially formed on the upper surface of the bank 97. For example, the light blocking layer 79 is formed only in the narrow viewing angle area NVA from a point that is half of the width of the bank 97, on the surface of the bank 97 disposed between the pixel electrode 91 of the narrow viewing angle area NVA and the pixel electrode 91 of the wide viewing angle area WVA. Accordingly, in the pixel P of the narrow viewing angle area NVA, the metal patterning layer 71 is deposited on the side wall of the bank 97. Further, in the pixel P of the wide viewing angle area WVA, the metal patterning layer 71 is also deposited on the side wall of the bank 97.

FIG. 9 shows a case where the metal patterning layer 71 is formed to have a width corresponding to the width of the pixel electrode 91 formed in the pixel P of the narrow viewing angle area NVA. In some cases, the metal patterning layer 71 may be formed to have a width slightly larger than the width of the pixel electrode 91.

In the light emitting display device according to the third aspect, the light blocking layer 79 is disposed around the pixel P, and is formed to expose at least the entirely of the emission area EA, or is formed to be slightly wider than the emission area EA. Therefore, the maximum aperture ratio may be ensured even in a narrow viewing angle area NVA.

Under the condition in which the narrow viewing angle mode should be further improved even though the aperture ratio is reduced, the light emitting display device according to the first aspect may be applied. On the other hand, for the condition in which an aperture ratio should be ensured and an image with high luminance is required even though the viewing angle is slightly wider in the narrow viewing angle mode, the light emitting display device according to the third aspect may be applied.

In the third aspect, the metal patterning layer 71 is deposited on the first protective layer 51, and disposed within the emission area EA in the narrow viewing angle area NVA and the emission area EA in the wide viewing angle area WVA. In addition, the metal patterning layer 71 is disposed, on the bank 97, from the emission area EA formed in the wide viewing angle area WVA to a position defined at ⅓ point, ½ point or ⅔ point of the separation width between the wide viewing angle area WVA and the narrow viewing angle area NVA.

In other word, in the third aspect, the border between the narrow viewing angle area NVA and the wide viewing angle area WVA is set on a position defined at ⅓ point, ½ point or ⅔ point of a separation width between the pixel electrode 91 of the narrow viewing angle area NVA and the pixel electrode 91 of the wide viewing angle area WVA.

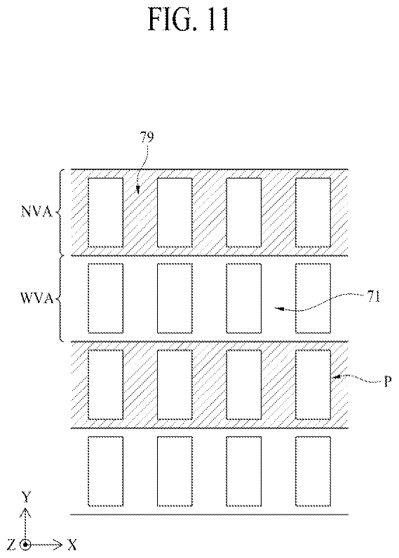

Hereinafter, referring to FIG. 10, the structure of the light emitting display device according to a second aspect of the present disclosure will be described. FIG. 10 is an enlarged plan view illustrating an arrangement structure of the light emitting display device according to a fourth aspect of the present disclosure.

In the case of the first aspect described with reference to FIGS. 1 to 5, one pixel P has a rectangular shape with a short side in the X-axis direction and a long side in the Y-axis direction. In the case of the light emitting display device according to the fourth aspect, as shown in FIG. 10, one pixel P may have a rectangular shape with a long side in the X-axis direction and a short side in the Y-axis direction. The descriptions about the structures of the metal patterning layer 71 and the light blocking layer 79 explained in the first to third aspects may be applied to the fourth aspect.

Hereinafter referring to FIG. 11, the structure of the light emitting display device according to a fifth aspect of the present disclosure will be described. FIG. 11 is an enlarged plan view illustrating an arrangement structure of the light emitting display device according to a fifth aspect of the present disclosure.

In the case of the first aspect described with reference to FIGS. 1 to 5, a narrow viewing angle area NVA and a wide viewing angle area WVA are respectively defined along the column direction in the matrix structure of the pixels P. In the case of the light emitting display device according to the fifth aspect as shown in FIG. 11, the narrow viewing angle area NVA and the wide viewing angle area WVA may be defined along the row direction in the matrix structure of the pixels P.

For example, pixels P corresponding to odd rows (or even rows) may be defined as a narrow viewing angle area NVA, and pixels P corresponding to even rows (or odd rows) may be defined as a wide viewing angle area WVA. In addition, the shape of each pixel P may have a rectangular shape with a long side in the X-axis direction and a short side in the Y-axis direction, as in the fourth aspect.

While describing the first to fifth aspects above, the pixels P disposed in each of the narrow viewing angle area NVA and the wide viewing angle area WVA are described as having the shape of only one sub-pixel. However, one pixel P may include a plurality of sub-pixels.

One pixel P shown in FIG. 5 may include a plurality of sub-pixels arranged consecutively in the horizontal direction. Alternatively, one pixel P may include a plurality of sub-pixels arranged sequentially in the vertical direction. For example, one pixel P may include a red sub-pixel, a green sub-pixel and a blue sub-pixel. As another example, one pixel P may include a red sub-pixel, a green sub-pixel, a white sub-pixel and a blue sub-pixel. Embodiments are not limited thereto. As an example, the sub-pixels of other colors are also possible.

In addition, one pixel shown in FIG. 10 may include a plurality of sub-pixels arranged consecutively in the horizontal or vertical direction. The arrangement of the plurality of sub-pixels is not limited thereto. As an example, the plurality of sub-pixels may be arranged in multiple rows or multiple columns, or be arranged in a non-linear shape.

The present disclosure is not limited thereto. One pixel P shown in FIG. 5 may be one sub-pixel having any one color among red, green and blue. In this case, three- or four-pixels P may be gathered together to form one unit pixel.

The features, structures, effects and so on described in the above example aspects of the present disclosure are included in at least one example aspect of the present disclosure, and are not necessarily limited to only one example aspect. Furthermore, the features, structures, effects and the like explained in at least one example aspect may be implemented in combination or modification with respect to other example aspects by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that aspects of the present disclosure cover the various substitutions, modifications, and variations of the present disclosure, provided they come within the scope of the appended claims and their equivalents. These and other changes may be made to the aspects in light of the above detailed description. In general, in the following claims, the terms used should not be construed to limit the claims to the specific example aspects disclosed in the specification and the claims, but should be construed to include all possible aspects along with the full scope of equivalents to which such claims are entitled. Accordingly, the claims are not limited by the disclosure.

1. A light emitting display device comprising:
a substrate including a first area and a second area adjacent to the first area;
a first pixel disposed in the first area;
a light blocking layer surrounding the first pixel in the first area;
a second pixel disposed in the second area; and
a metal patterning layer covering and surrounding the second pixel in the second area.

2. The light emitting display device according to claim 1, wherein the light blocking layer is disposed from an edge of a first emission area of the first pixel to a point defined between ⅓ and ½ of a separation width between the first emission area of the first pixel and a second emission area of the second pixel.

3. The light emitting display device according to claim 1, wherein the light blocking layer includes a metal material with a light absorption or light reflectance of 90%, at least, and
wherein the metal patterning layer includes an organic material with a light transmittance of 90%, at least.

4. The light emitting display device according to claim 1, further comprising:
a first pixel electrode in the first pixel;
a second pixel electrode in the second pixel;
a bank disposed between the first pixel electrode and the second pixel electrode to define a first emission area of the first pixel and a second emission area of the second pixel;
an emission layer over the first pixel electrode, the bank and the second pixel;
a common electrode on the emission layer; and
a first protective layer on the common electrode.

5. The light emitting display device according to claim 4, wherein the metal patterning layer is disposed on the first protective layer, and disposed within the first emission area and the second emission area, and
wherein the metal patterning layer is further disposed from the second emission area to a position on the bank defined at ½ to ⅔ of a separation width between the first emission area and the second emission area.

6. The light emitting display device according to claim 4, wherein the light blocking layer is disposed from the first emission area on the first protective layer to a position defined at ⅓ to ½ between the first emission area and the second emission area.

7. The light emitting display device according to claim 4, wherein the metal patterning layer and the light blocking layer is disposed on the first protective layer, and
wherein the light emitting display device further comprises: a second protective layer on the metal patterning layer and the light blocking layer.

8. The light emitting display device according to claim 1, wherein the first area and the second area have a strip shape extending in a first direction, and are arranged alternately in a second direction different from the first direction.

9. The light emitting display device according to claim 8, wherein the first direction is a vertical direction on the substrate in a plan view, and
wherein the second direction is a horizontal direction on the substrate in the plan view.

10. The light emitting display device according to claim 8, wherein the first direction is a horizontal direction on the substrate in a plan view, and
wherein the second direction is a vertical direction on the substrate in the plan view.

11. The light emitting display device according to claim 1, wherein a first viewing angle of the first area is 30-degree, at most, and
wherein a second viewing angle of the second area is 70-degree, at least.

12. The light emitting display device according to claim 1, wherein, in a narrow viewing angle mode, the first pixel emits lights, and the second pixel does not emit lights.

13. The light emitting display device according to claim 1, wherein the light blocking layer includes at least one of ytterbium (Yb), calcium (Ca), titanium (Ti), magnesium (Mg), barium (Ba), silver (Ag), silver-ytterbium (Ag—Yb) alloy and silver-magnesium (Ag—Mg) alloy.

14. The light emitting display device according to claim 13, wherein the metal patterning layer includes a 3-(Biphenyl-4-yl)-5-(4-tert1butylphenyl)-4-phenyl-4H-1,2,4-triazole (TAZ).

15. The light emitting display device according to claim 1, wherein the light blocking layer is disposed at an area where the metal patterning layer is not disposed.
